(19) United States
(12) Patent Application Publication
(10) Pub. No.: US 2013/0256704 A1
(43) Pub. Date: Oct. 3, 2013

(54) LED, Backlight Module, and LCD Device

(71) Applicants: Yuchun Hsiao, Shenzhen (CN); Guofu Tang, Shenzhen (CN)

(72) Inventors: Yuchun Hsiao, Shenzhen (CN); Guofu Tang, Shenzhen (CN)

(21) Appl. No.: 13/503,849

(22) PCT Filed: Mar. 31, 2012
(86) PCT No.: PCT/CN2012/073367

§ 371 Date: Apr. 24, 2012

(30) Foreign Application Priority Data
Mar. 29, 2012 (CN) 20120087590.7

(51) Int. Cl. H01L 33/62

(52) U.S. Cl. 257/88; 257/99; 257/E33.062

(57) ABSTRACT

The invention provides a LED, a backlight module, and a LCD device. The LED includes an inner cavity. The bottom of the inner cavity is provided with a chip. Four side walls are arranged around the bottom of the inner cavity. Both ends of the chip are respectively connected with electrodes. Two opposite side walls of the bottom of the inner cavity are provided with at least one convex step surface, and the electrodes at the two ends of the chip are extended to the step surface from the bottom of the inner cavity; the other two side walls adjacent to the step surface are provided with at least one inclined surface which makes an obtuse angle with the bottom of the inner cavity. By selecting the inclination angle of different inclined surfaces, the invention can freely control the scattering range of the emitted light, has strong adaptability, and is suitable for being used as a backlight source of the LCD device. When light enters from the side, the large light emitting angle enables the light to be uniformly emitted into a light guide panel, thereby reducing the phenomenon of hot spots.

### TECHNICAL FIELD

The invention relates to the field of electronic displays, and more particularly to a light emitting diode (LED), a backlight module, and a liquid crystal display (LCD) device.

### BACKGROUND

LEDs, with a small volume and high luminous efficiency, are widely applied to the field of display, lighting and the like. Generally, the LED is used as a backlight source in a LCD Device.

FIG. 1 shows a common structure of a LED. A chip is fixed to an electrode via a silver adhesive. The electrode is made of metal material. The LED frame is made of plastic material or ceramic material. The upper part of the electrode is generally filled with a potting adhesive such as epoxy resin and silica gel. These materials have different expansion rate, and thus crack occurs at the joint of the plastic material and the electrode and the joint of the potting adhesive and the electrode. The crack will grow along the electrode, and the outside air enters along the crack at the joints and diffuses along the electrode surface. The main component of the silver adhesive on the electrode is Ag which can react with the oxygen in air to generate silver oxide which is an insulator. Thus, the conduction between the chip and the electrode is increasingly poor as time passes by.

FIG. 2 and FIG. 3 show a conventional LED scheme employing a mode of down set, namely a chip is arranged at the bottom of an electrode, and the down set is formed by a metal electrode using punching. The contact area between the electrode and the potting adhesive is increased, the air diffusing path is increased, and the air diffusing force is continually reduced before contacting with the silver adhesive. Therefore, the silver adhesive is prevented from generating silver oxide.

As shown in FIG. 4, the side light emitted by the chip is directly irradiated to the side arm of the down set. Thus, the scope of the light emitting angle is reduced, namely the light is increasingly gathered. When the LED is used in an edge-light backlight module (not shown in the sectional view), the more dispersive the left and right light of the LED is, the more difficult the phenomenon of hot spots occurs; the more connivent the upper and lower light is, the less the lost light is. All the down set arrangement of the chips of the common LEDs does not benefit light dispersal.

### SUMMARY

In view of the above-described problems, the aim of the invention is to provide a LED, a backlight module, and a LCD device capable of reducing electrode oxidation and reducing the phenomenon of hot spots.

The aim of the invention is achieved by the following technical schemes.

A LED comprises an inner cavity; the bottom of the inner cavity is provided with a chip, four side walls are arranged around the bottom of the inner cavity, both ends of the chip are respectively connected with electrodes, the bottom of the inner cavity are provided with at least one convex step surface at two opposite side walls, and the electrodes at the two ends of the chip are extended to the step surface from the bottom of the inner cavity; the other two side walls adjacent to the step surface are provided with at least one inclined surface which forms an obtuse angle with the bottom of the inner cavity.

Preferably, one of the two side walls adjacent to the step surface is provided the inclined surface, and the inclined surface intersects the bottom of the inner cavity. This is one specific mode for arranging the inclined surface.

Preferably, both the two side walls adjacent to the step surface are respectively provided with inclined surfaces, and the inclined surfaces intersect the bottom of the inner cavity. This is another specific mode for arranging the inclined surface. Both the two sides are provided with inclined surfaces, further expanding the light emitting scope.

Preferably, the included angles between the inclined surfaces of the two side walls adjacent to the step surface and the bottom are inconsistent. The inclination angles of the two inclined surfaces can be adjusted in accordance with the specific application occasion, so as to emit the light at an optimum angle.

Preferably, the included angles between the inclined surfaces of the two side walls adjacent to the step surface and the bottom are consistent. The angles are consistent and easy to process.

Preferably, the electrode at one end of the chip is connected with a Zener which is arranged on the step surface; the electrode at the other end of the chip is directly extended outside the inner cavity from the bottom of the inner cavity, and the side wall corresponding thereto is also provided with an inclined surface which intersects the bottom of the inner cavity. The Zener can prevent the chip from being broken down by static electricity, but the Zener can absorb light; therefore, the Zener can protect the chip and cannot absorb light by arranging the Zener on the step surface. The side wall of the other side is not provided with a step surface, but provided with an inclined surface. Thus, three side walls of the inner cavity are provided with inclined surfaces, thereby obtaining a larger light emitting angle.

Preferably, the acute angle that the inclined surface intersects the bottom plane of the inner cavity is between 0.5° and 89°.

Preferably, the acute angle that the inclined surface intersects the bottom plane of the inner cavity is between 30° and 60°.

A backlight module comprises a LED mentioned above.

A LCD device comprises a backlight module mentioned above.

The invention designs the down set, to increase the contact area between the electrode and the potting adhesive, and reduce electrode oxidation. In addition, the two side walls adjacent to the electrodes of the inner cavity are provided with inclined surface(s); thus, the side light emitted by the chip is directly reflected outside by the inclined surface, thereby expanding the light emitting angel. By selecting the inclination angle of different inclined surfaces, the invention can freely control the scattering range of the emitted light, has strong adaptability, and is suitable for being used as a backlight source of the LCD device. When light enters from the side, the large light emitting angle enables the light to be uniformly emitted into a light guide panel, thereby reducing the phenomenon of hot spots.

### BRIEF DESCRIPTION OF FIGURES

FIG. 1 is a schematic diagram of an air diffusing path of a conventional LED without down set;

FIG. 2 is a schematic diagram of a conventional air diffusing path of a LED with down set;

FIG. 3 is a three-dimensional view of a conventional LED with down set;

FIG. 4 is a schematic diagram of a light diffusing path of a conventional LED with down set;

FIG. 5 is a schematic diagram of light diffusing path of a conventional LED with down set in a backlight module;

FIG. 6 is a structure diagram of example 1 of the invention;

FIG. 7 is a structure diagram of example 2 of the invention;

FIG. 8 is a structure diagram of example 3 of the invention; and

FIG. 9 is a schematic diagram of the invention along an A-A line.

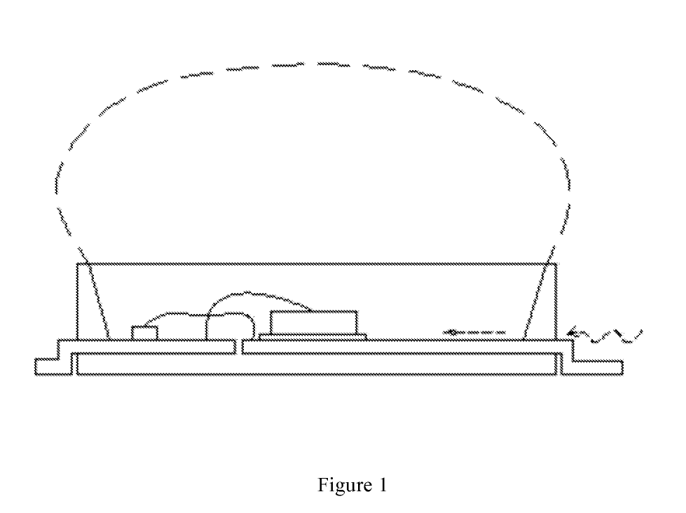

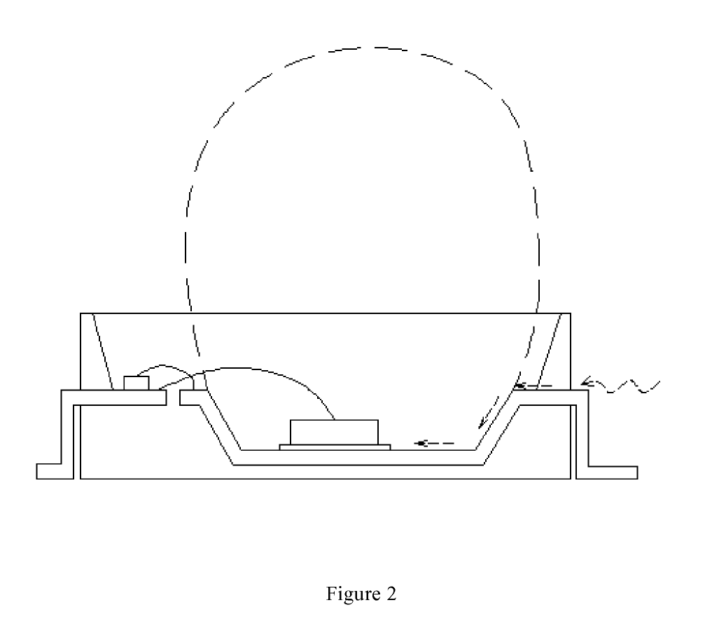

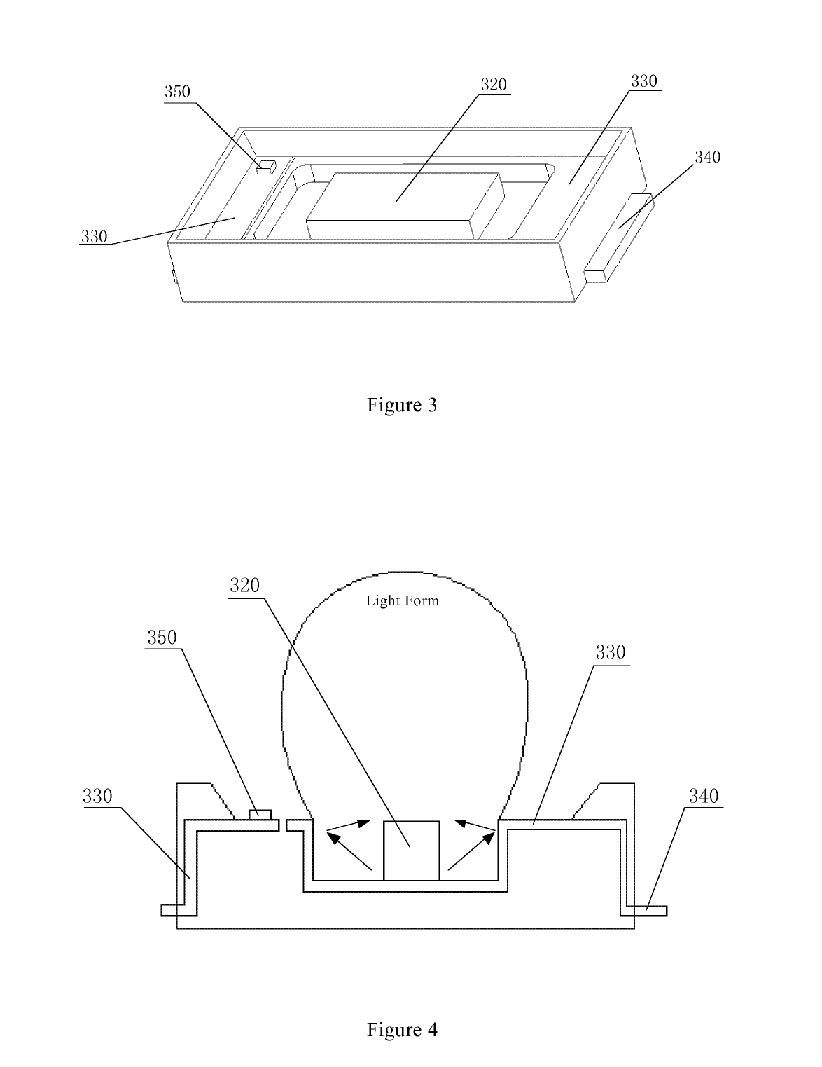

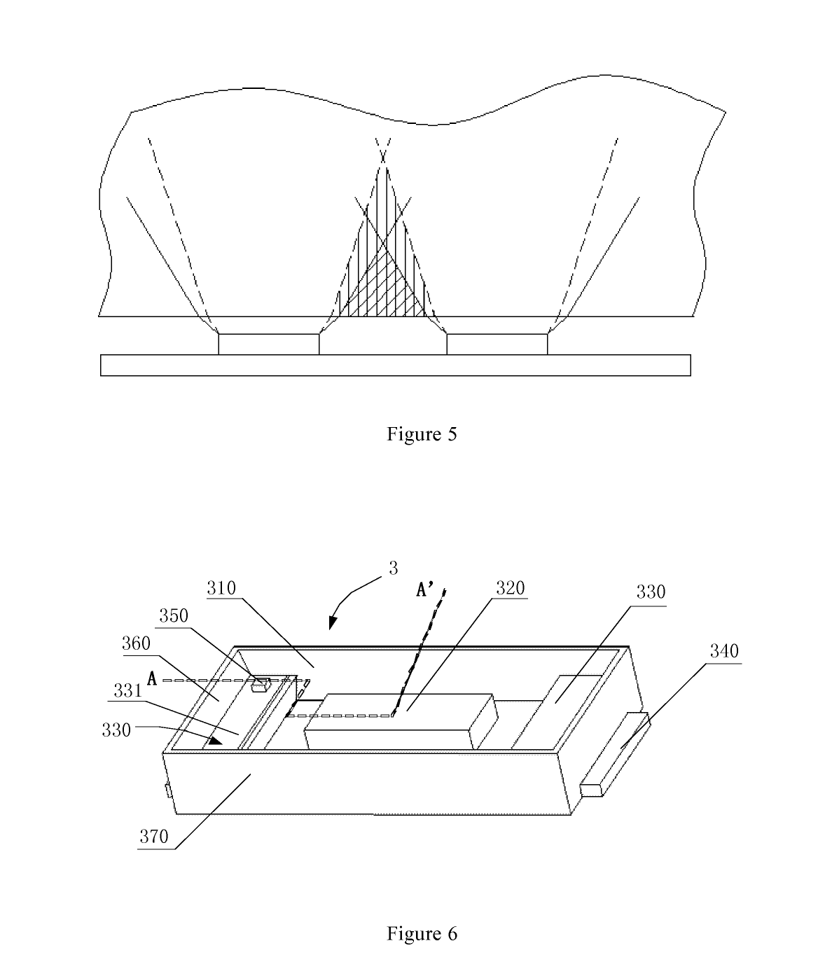

Legends: 3. inner cavity; 310. first inclined surface; 311. second inclined surface; 320. chip; 330. electrode; 331. step surface; 340. pin; 350. Zener; 360. third inclined surface; 370. side wall.

### DETAILED DESCRIPTION

The invention will further be described in detail in accordance with the figures and the preferable examples.

A LCD device comprises a backlight module. A LED is used as a backlight source in the backlight module.

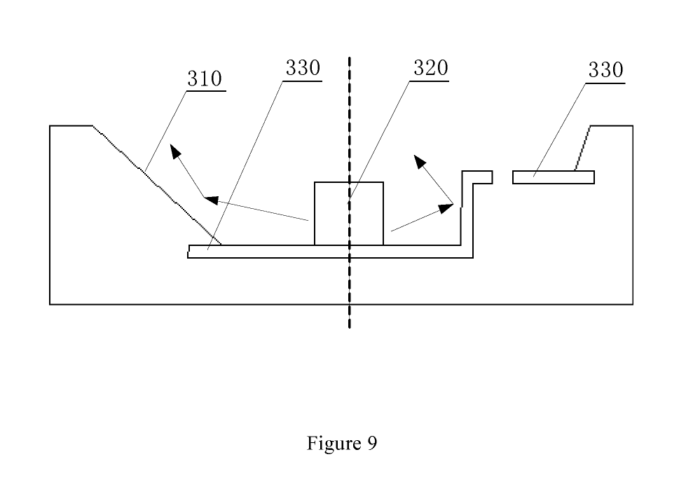

As shown in FIGS. 6-9, the LED comprises an inner cavity 3. The bottom of the inner cavity 3 is provided with a chip 320. Four side walls 370 are arranged around the bottom of the inner cavity 3. Both ends of the chip 320 are respectively connected with electrodes 330. Two opposite side walls 370 of the bottom of the inner cavity 3 are provided with at least one convex step surface, and the electrode 330 is extended from the inner cavity and forms a pin 340 outside the inner cavity. The electrodes at the two ends of the chip are extended to the step surface 331 from the bottom of the inner cavity; the other two side walls adjacent to the step surface 331 are provided with inclined surface(s).

### Example 1

As shown in FIG. 6, one of the two side walls adjacent to the step surface is provided a first inclined surface 310. The acute angle that the first inclined surface 310 intersects the bottom plane of the inner cavity is between 0.5° and 89°, preferably, between 30° and 60°. The electrodes 330 can be arranged on the two short side walls of the inner cavity, and accordingly, the first inclined surface 310 can be arranged on the long side wall of the inner cavity. Optionally, the electrodes 330 can be arranged on the two long side walls of the inner cavity, and accordingly, the first inclined surface 310 can be arranged on the short side wall of the inner cavity.

To prevent the chip from being broken down by static electricity, one of the electrodes is connected with a Zener in series. The Zener is arranged on the step surface. Thus, the Zener can be prevented from absorbing light.

### Example 2

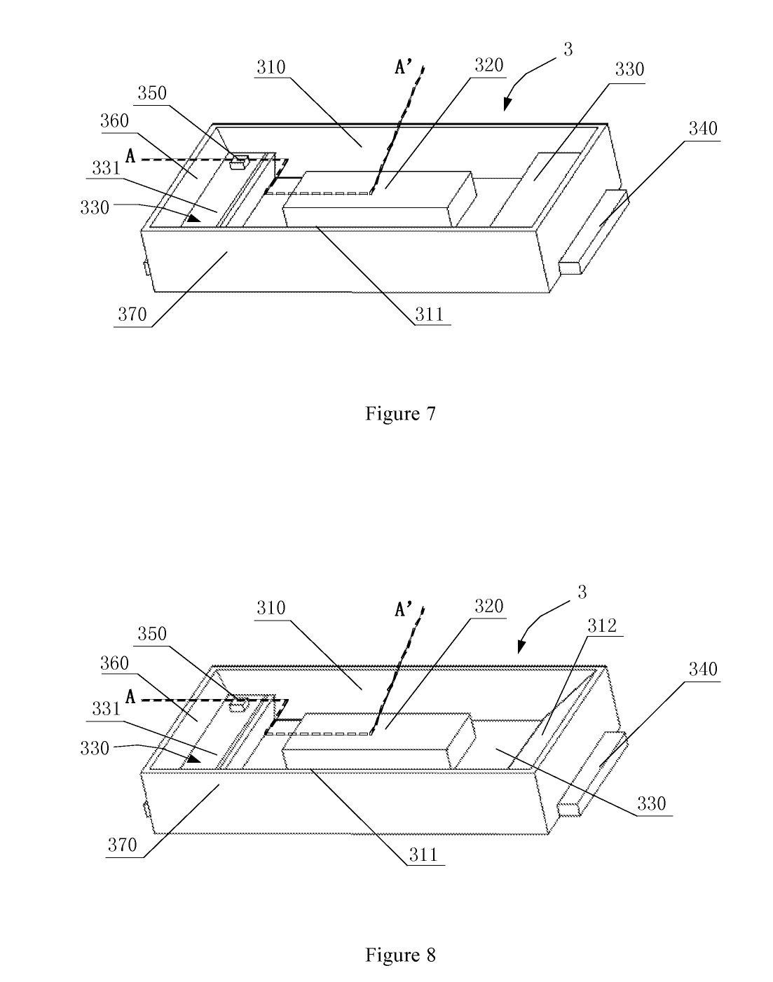

As shown in FIG. 7, both the two side walls adjacent to the step surface are respectively provided with a first inclined surface 310 and a second inclined surface 311. The acute angle that the inclined surfaces intersect the bottom plane of the inner cavity is between 0.5° and 89°, preferably, between 30° and 60°. The electrodes 330 can be arranged on the two short side walls of the inner cavity, and accordingly, the first inclined surface 310 and the second inclined surface 311 can be arranged on the long side walls of the inner cavity. Optionally, the electrodes 330 can be arranged on the two long side walls of the inner cavity, and accordingly, the first inclined surface 310 and the second inclined surface 311 can be arranged on the short side walls of the inner cavity.

To prevent the chip from being broken down by static electricity, one of the electrodes is connected with a Zener in series. The Zener is arranged on the step surface. Thus, the Zener can be prevented from absorbing light.

### Example 3

As shown in FIG. 8, one electrode 330 provided with a Zener 350 is convex to form a step surface 331 at the bottom of the inner cavity, the other electrode 330 is arranged at the bottom of the inner cavity, and one side thereof corresponding to the inner cavity is provided with an inclined surface to form a third inclined surface 360. The acute angle that the inclined surface intersects the bottom plane of the inner cavity is between 0.5° and 89°, preferably, between 30° and 60°. The example can be randomly combined with either the aforementioned first example or second example, particularly the second example. Thus, three side walls of the four side walls of the inner cavity are respectively provided with an inclined surface to form the first inclined surface 310, the second inclined surface 311, and the third inclined surface 360, thereby ensuring the maximum light emitting range.

The electrodes 330 are arranged on the two short side walls of the inner cavity, and accordingly, the first inclined surface 310 and the second inclined surface 311 are arranged on the long side walls of the inner cavity. Optionally, the electrodes 330 can be arranged on the two long side walls of the inner cavity, and accordingly, the first inclined surface 310 and the second inclined surface 311 can be arranged on the short side walls of the inner cavity.

FIG. 7 shows an example of the invention. The electrode 330 with a Zener 350 is provided with a step surface 331, and light is sideways emitted to the side arm of the step surface 331 and then gathered. Thus, the light emitting angle is narrowed. However, after light is emitted to the inclined surface (take the first inclined surface 310 as an example) of the inner cavity, the light reflected by the inclined surface is not gathered any longer, but is continuously diffused outwards, thereby expanding the light emitting angle.

The invention designs the down set, to increase the contact area between the electrode and the potting adhesive, and reduce electrode oxidation. In addition, the two side walls adjacent to the electrodes of the inner cavity are provided with inclined surface(s); thus, the side light emitted by the chip is directly reflected outside by the inclined surface, thereby expanding the light emitting angel. By selecting the inclination angle of different inclined surfaces, the invention can freely control the scattering range of the emitted light, has strong adaptability, and is suitable for being used as a backlight source of the LCD device. When light enters from the side, the large light emitting angle enables the light to be uniformly emitted into the light guide panel, thereby reducing the phenomenon of hot spots.

The invention is described in detail in accordance with the above contents with the specific preferred examples. However, this invention is not limited to the specific examples. For the ordinary technical personnel of the technical field of the present invention, on the premise of keeping the conception of the invention, the technical personnel can also make simple deductions or replacements, and all of which should be considered to belong to the protection scope of the invention.

We claim:

1. A LED, comprising: an inner cavity; wherein the bottom of said inner cavity is provided with a chip, four side walls are arranged around the bottom of said inner cavity, both ends of said chip are respectively connected with electrodes, the bottom of the inner cavity are provided with at least one convex step surface at two opposite side walls, and the electrodes at the two ends of said chip are extended to said step surface from the bottom of said inner cavity; the other two side walls adjacent to the step surface are provided with at least one inclined surface which forms an obtuse angle with the bottom of said inner cavity.

2. The LED of claim 1, wherein one of said two side walls adjacent to said step surface is provided the inclined surface; said inclined surface intersects the bottom of said inner cavity.

3. The LED of claim 1, wherein both said two side walls adjacent to said step surface are respectively provided with inclined surfaces; said inclined surfaces intersect the bottom of said inner cavity.

4. The LED of claim 3, wherein the included angles between the inclined surfaces of said two side walls adjacent to said step surface and the bottom are inconsistent.

5. The LED of claim 3, wherein the included angles between the inclined surfaces of said two side walls adjacent to said step surface and the bottom are consistent.

6. The LED of claim 1, wherein the electrode at one end of said chip is connected with a Zener which is arranged on said step surface; the electrode at the other end of said chip is directly extended outside the inner cavity from the bottom of said inner cavity, and the side wall corresponding thereto is also provided with an inclined surface which intersects the bottom of said inner cavity.

7. The LED of claim 1, wherein the acute angle that said inclined surface intersects the bottom plane of said inner cavity is between 0.5° and 89°.

8. The LED of claim 7, wherein the acute angle that said inclined surface intersects the bottom plane of said inner cavity is between 30° and 60°.

9. A backlight module, comprising: an LED; wherein said LED comprises an inner cavity; the bottom of said inner cavity is provided with a chip, four side walls are arranged around the bottom of said inner cavity, both ends of said chip are respectively connected with an electrode, the bottom of the inner cavity are provided with at least one convex step surface at two opposite side walls, and the electrodes at the two ends of said chip are extended to said step surface from the bottom of said inner cavity; the other two side walls adjacent to said step surface are provided with at least one inclined surface which forms an obtuse angle with the bottom of said inner cavity.

10. The backlight module of claim 9, wherein one of said two side walls adjacent to said step surface is provided the inclined surface, and said inclined surface intersects the bottom of said inner cavity.

11. The backlight module of claim 9, wherein both said two side walls adjacent to said step surface are respectively provided inclined surfaces, and said inclined surfaces intersect the bottom of said inner cavity.

12. The backlight module of claim 11, wherein the included angles between the inclined surfaces of said two side walls adjacent to said step surface and the bottom are inconsistent.

13. The backlight module of claim 11, wherein the included angles between the inclined surfaces of said two side walls adjacent to said step surface and the bottom are consistent.

14. The backlight module of claim 9, wherein the electrode at one end of said chip is connected with a Zener, and the Zener is arranged on said step surface; the electrode at the other end of said chip is directly extended outside the inner cavity from the bottom of said inner cavity, and the side wall corresponding thereto is also provided with an inclined surface which intersects the bottom of said inner cavity.

15. The backlight module of claim 9, wherein the acute angle that said inclined surface intersects the bottom plane of said inner cavity is between 0.5° and 89°.

16. The backlight module of claim 15, wherein the acute angle that said inclined surface intersects the bottom plane of said inner cavity is between 30° and 60°.

17. A LCD, comprising: a backlight module of claim 9.
